(19) United States
(12) Patent Application Publication
(10) Pub. No.: US 2025/0280668 A1
(43) Pub. Date: Sep. 4, 2025

(54) DISPLAY DEVICE

(71) Applicant: LG Display Co., Ltd., Seoul (KR)

(72) Inventors: Junsik HWANG, Seoul (KR); SungHee KIM, Paju-si (KR); SuJeong Lee, Seoul (KR); Kaapjoon Park, Seoul (KR)

(73) Assignee: LG Display Co., Ltd., Seoul (KR)

(21) Appl. No.: 19/003,113

(22) Filed: Dec. 27, 2024

(30) Foreign Application Priority Data
Feb. 29, 2024 (KR) 10-2024-0029870

(51) Int. Cl. H10K 59/124; H10K 59/38

(52) U.S. Cl. CPC H10K 59/124; H10K 59/38

(57) ABSTRACT

A display device including a substrate; a thin film transistor disposed on the substrate; a planarization layer disposed on the thin film transistor; a light emitting diode disposed on the planarization layer; and an encapsulation layer disposed so as to cover the plurality of light emitting diodes, and in which the planarization layer includes a first planarization layer which is disposed so as to cover the thin film transistor and a second planarization layer which is disposed so as to cover at least a part of the first planarization layer and a refractive index of the first planarization layer is lower than that of the second planarization layer, and the first planarization layer includes an acrylic binder and (meth)acrylic acid-benzyl (meth)acrylic acid copolymer.

### CROSS-REFERENCE TO RELATED APPLICATIONS

This application claims the benefit of the priority to Korean Patent Application No. 10-2024-0029870 filed on Feb. 29, 2024, in the Korean Intellectual Property Office, the disclosure of which is hereby incorporated by reference in its entirety.

### BACKGROUND

### 1. Technical Field

The present disclosure relates to a display device, and more particularly, to a display device which improves a reliability with excellent light extraction efficiency by introducing a low refractive planarization layer.

### 2. Description of the Related Art

The organic light emitting display device OLED is a self-emitting display device. Therefore, the organic light emitting display device can be manufactured in a lightweight and small thickness, and is advantageous in terms of power consumption due to low-voltage operation and also has the advantages of excellent color expression, response speed, viewing angle, and contrast ratio.

Such an organic light emitting display device may be driven in a top emission type in which light emitted from an organic light emitting diode is emitted to the top of the organic light emitting display device and a bottom emission type in which light is emitted to the bottom of the organic light emitting display device. That is, in the bottom emission type organic light emitting display device, light emitted from the organic light emitting diode is emitted toward a bottom surface of the substrate on which a thin film transistor for driving the organic light emitting display device is formed. In such a bottom emission type organic light emitting display device, light emitted from an organic emission layer needs to be extracted to the outside of the organic light emitting display device. However, some of light is captured in the organic light emitting display device due to the total reflection of the substrate and the other is captured in the organic light emitting display device due to the total reflection of a layer which is formed of a metal, such as an anode. Therefore, according to the bottom emission type, it is important to improve the light extraction efficiency to the outside of the organic light emitting display device to improve the efficiency.

### SUMMARY

A method for forming layers of the organic light emitting display device, such as a planarization layer, an anode, an organic emission layer, and a cathode to have a micro lens array structure has been proposed to improve the light extraction efficiency of the organic light emitting display device. However, there is a difficulty in the process of forming a micro lens shape in each layer and there is a problem such as a rainbow mura.

Therefore, in order to provide a flat surface while improving the light extraction efficiency, a structure in which a high refractive planarization layer is formed in a position adjacent to an anode having a higher refractive index and a low refractive planarization layer is formed in a position adjacent to a substrate has been proposed. As described above, when planarization layers having different refractive indices are laminated, in order to maximize the light extraction efficiency, a difference in refractive indices needs to be adjusted to 0.2 or larger.

In the related art, in order to implement a planarization layer having a low refractive characteristic, a fluorine resin with a low refractive index was used. However, the fluorine resin has hydrophobicity, which causes a problem of poor adhesiveness with the upper and lower layers. Further, when a low refractive planarization layer is formed by dispersing low-refractive nano particles in a base resin, the low refractive characteristic is excellent, but in order to form the micro lens array structure, the light absorption is interrupted during the photolithography process so that it is difficult to form a lens pattern. Therefore, a method of forming a low refractive planarization layer using siloxane-acrylic fluorine resin has been proposed. In this case, the fluorine component caused a poor adhesiveness with upper and lower layers and during the process of forming an anode of the light emitting diode, after depositing an electrode material, the electrode material was lost due to insufficient adhesiveness during the development process, which caused a lighting failure, etc. Further, when the low refractive planarization layer was formed with the material as described above, as exposure, development, and baking steps proceeded, the roughness of the low refractive planarization layer was increased, which may cause the degradation of the luminous efficiency. Further, the low refractive planarization layer of the related art had a problem of the lowered transmittance in a short wavelength range due to yellowing after high temperature reliability test.

Therefore, an object of the present disclosure is to provide a display device which includes a low refractive planarization layer having a low refractive index of 1.50 or lower and a high refractive planarization layer having a higher refractive index to improve a light extraction efficiency.

Further, an object of the present disclosure is to provide a display device which does not include a fluorine compound having a hydrophobicity, but provides a low refractive planarization layer having a low refractive characteristic and improved adhesiveness with upper and lower layers to provide excellent processability and reliability.

Further, an object of the present disclosure is to provide a display device which has an improved processability by providing a low refractive planarization layer which enables photo patterning to easily form a lens shape.

Objects of the present disclosure are not limited to the above-mentioned objects, and other objects, which are not mentioned above, can be clearly understood by those skilled in the art from the following descriptions.

To achieve these and other advantages and in accordance with objects of the disclosure, as embodied and broadly described herein, a display device includes a substrate; a thin film transistor disposed on the substrate; a planarization layer disposed on the thin film transistor; a light emitting diode disposed on the planarization layer; and an encapsulation layer disposed so as to cover the plurality of light emitting diodes, and in which the planarization layer includes a first planarization layer which is disposed so as to cover the thin film transistor and a second planarization layer which is disposed so as to cover at least a part of the first planarization layer and a refractive index of the first planarization layer is lower than that of the second planarization layer, and the first planarization layer includes an acrylic binder and (meth)acrylic acid-benzyl (meth)acrylic acid copolymer.

Other detailed matters of the example embodiments are included in the detailed description and the drawings.

According to the present disclosure, a display device which includes a first planarization layer having a low refractive index of 1.50 or lower and a second planarization layer having a higher refractive index to improve a light extraction efficiency is provided.

According to the present disclosure, the first planarization layer does not include a fluorine compound having a hydrophobicity and low refractive particles, but has a low refractive characteristic so that the adhesiveness with upper and lower layers is excellent. Therefore, a display device with excellent processability and reliability is provided.

According to the present disclosure, the first planarization layer can be photo-patterned to easily form a lens shape and forms a micro lens structure on an interface of the first planarization layer and the second planarization layer without having a difficult in the process to provide a display device with a significantly improved light extraction efficiency.

The effects according to the present disclosure are not limited to the contents exemplified above, and more various effects are included in the present specification.

It is to be understood that both the foregoing general description and the following detailed description of the present disclosure are by way of example and are intended to provide further explanation of the disclosure.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a cross-sectional view of a display device according to an example embodiment of the present disclosure;

FIG. 2 is a graph illustrating a result of evaluating high temperature and high humidity reliability of Example 1; and

FIG. 3 is a graph illustrating a result of evaluating high temperature reliability of Comparative Example 1.

### DETAILED DESCRIPTION

Reference will now be made in detail to some of the examples and embodiments of the present disclosure illustrated in the accompanying drawings. Wherever possible, the same reference numbers will be used throughout the drawings to refer to the same or like parts.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

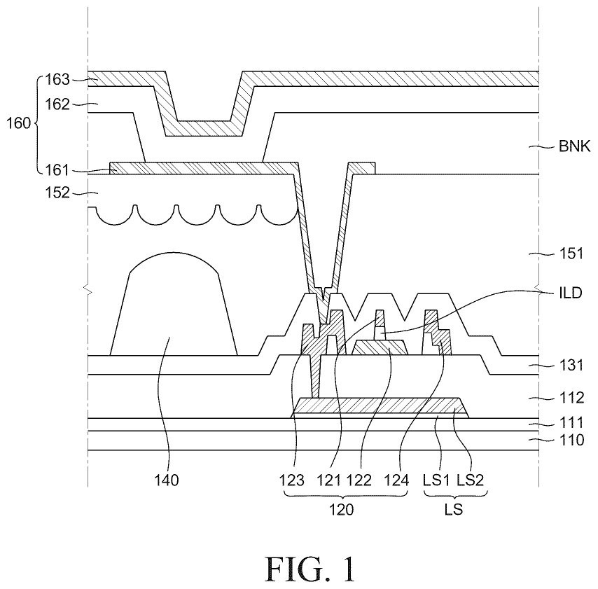

FIG. 1 is a cross-sectional view of a display device according to an example embodiment of the present disclosure.

With reference to FIG. 1, the display device 100 according to the example embodiment of the present disclosure includes a substrate 110, a first buffer layer 111, a light shielding layer LS, a second buffer layer 112, a thin film transistor 120, a passivation layer 131, a color filter 140, a first planarization layer 151, a second planarization layer 152, and a light emitting diode 160.

The substrate 110 supports elements which configure the display device 100. The substrate 110 may be formed of an insulating material. For example, the substrate 110 may be a glass substrate or may be formed of a polymer material. For example, the polymer may be selected from polyethylene terephthalate, polyimide, etc., but is not limited thereto. The substrate 110 may be configured as a single layer or a multi-layered structure.

The substrate 110 includes areas defined as an active area and a non-active area. The active area is an area in which an image is displayed. In the active area, a plurality of sub pixels which displays images and a driving circuit for driving the plurality of sub pixels may be disposed. Each of the plurality of sub pixels is an individual unit which emits light and the light emitting diode 160 is formed in each of the plurality of sub pixels.

The plurality of sub pixels may include a red sub pixel, a green sub pixel, and a blue sub pixel, but is not limited thereto. The driving circuit may include various transistors, storage capacitors, and wiring lines for driving the plurality of sub pixels. For example, the driving circuit may be configured by various components, such as a driving transistor, a switching transistor, a sensing transistor, a storage capacitor, a gate line, and a data line, but is not limited thereto.

The non-active area is an area which is disposed so as to enclose the active area and does not actually display images. In the non-active area, various wiring lines and driving ICs for driving a sub pixel disposed in the active area are disposed. For example, in the non-active area, various driving ICs, such as a gate driver IC and a data driver IC, may be disposed, but the present disclosure is not limited thereto.

The first buffer layer 111 may be disposed on the substrate 110. The first buffer layer 111 protects the thin film transistor 120 and the light emitting diode 160 from moisture, external air, and foreign materials permeating from the outside. Further, the first buffer layer 111 may suppress the change of the characteristic of the thin film transistor 120 caused by hydrogen or a foreign material which is diffused from the substrate 110 during a forming process of a thin film transistor. The first buffer layer 111 may be formed of an inorganic insulating material. For example, the first buffer layer 111 may be formed of a material selected from a silicon oxide film, a silicon nitride film, or a silicon oxynitride film, but is not limited thereto. The first buffer layer 111 is formed as a single layer or a multi-layered structure. For example, the first buffer layer 111 may be formed by a multi-layered structure in which a silicon oxide film and a silicon nitride film are laminated, but is not limited thereto.

The light shielding layer LS may be disposed on the first buffer layer 111. The light shielding layer LS blocks light such as ultraviolet ray incident from the outside of the display device 100 to suppress a damage of the thin film transistor 120 due to the light, specifically the damage of the active layer 121. Therefore, the light shielding layer LS is disposed so as to overlap the active layer 121 of the thin film transistor 120.

As illustrated in FIG. 1, in the thin film transistor 120 with a structure in which the gate electrode 122 is disposed on the active layer 121, the active layer 121 may be damaged by the ultraviolet rays incident from the substrate 110. The light shielding layer LS is disposed between the substrate 110 and the active layer 121 to protect the active layer 121 from the ultraviolet rays.

The light shielding layer LS may be formed of a metal material. As the light shielding layer LS is formed of a metal material, the active layer 121 may be protected from the ultraviolet rays, but the contrast ratio of the display device 100 may be degraded due to high reflectance. Therefore, in order to minimize the degradation of the contrast ratio, the light shielding layer LS may be formed with a low reflective metal. For example, the light shielding layer LS may be formed to include one metal selected from copper (Cu), molybdenum (Mo), aluminum (Al), chrome (Cr), gold (Au), titanium (Ti), nickel (Ni), and niobium (Nd), but is not limited thereto.

The light shielding layer LS may be formed as a single layer or multiple layers. With reference to FIG. 1, the light shielding layer LS may include a first layer LS1 and a second layer LS2 on the first layer LS1. At this time, the first layer LS1 may be formed to include a relatively low reflective metal to reduce external light reflectance. For example, the first layer LS1 may be formed to include one or more metals of molybdenum (Mo), nickel (Ni), copper (Cu), and tungsten (W). Further, in order to reduce the reflectance, the first layer LS1 may further include a metal oxide, such as MoO₂, In₂O₃, SnO₂, ZnO, Nb₂O₅, WO₃, TiO₂, ZrO₂, and HfO₂, but is not limited thereto.

For example, the second layer LS2 may be formed to include one metal selected from copper (Cu), molybdenum (Mo), aluminum (Al), chrome (Cr), gold (Au), titanium (Ti), nickel (Ni), and niobium (Nd), but is not limited thereto.

Even though in the drawing, it is illustrated that the light shielding layer LS has a double-layered structure, it is not limited thereto and the light shielding layer may be formed as a single layer or formed as triple or more multiple layers.

The second buffer layer 112 is disposed on the light shielding layer LS. The second buffer layer 112 insulates the light shielding layer LS from the thin film transistor 120. Further, during the process of forming the thin film transistor 120, the second buffer layer 112 blocks impurities flowing from the substrate 110 and the light shielding layer LS. For example, the second buffer layer 112 may be formed of a material selected from a silicon oxide film, a silicon nitride film, or a silicon oxynitride film, but is not limited thereto.

The thin film transistor 120 is disposed on the second buffer layer 112. The thin film transistor 120 includes an active layer 121, a gate electrode 122, a source electrode 123, and a drain electrode 124.

The active layer 121 is disposed on the second buffer layer 112. As described above, the active layer 121 is disposed on the second buffer layer 112 so as to overlap the light shielding layer LS. Therefore, the damage of the active layer 121 due to the ultraviolet ray may be suppressed. The active layer 121 may be formed of an oxide semiconductor material or polycrystalline silicon. When the active layer 121 is formed of polycrystalline silicon, the light shielding layer LS therebelow may be omitted. When the active layer 121 is formed of polycrystalline silicon, impurities may be doped on both edges of the active layer 121.

An insulating film ILD which is formed of an insulating material is disposed on the active layer 121. The insulating film ILD is disposed between the active layer 121 and the gate electrode 122 to insulate the active layer 121 and the gate electrode 122 from each other. The insulating film ILD may be formed of a material selected from a silicon oxide film, a silicon nitride film, and a silicon oxynitride film, but is not limited thereto.

The gate electrode 122 which is formed of a conductive material, such as metal, may be disposed on the insulating film ILD. The gate electrode 122 is disposed so as to overlap a channel region of the active layer 121. For example, the gate electrode 122 may be configured by copper (Cu), aluminum (Al), molybdenum (Mo), nickel (Ni), titanium (Ti), chrome (Cr), or an alloy thereof, but is not limited thereto.

The source electrode 123 and the drain electrode 124 may be disposed on the insulating film ILD as the same as the gate electrode 122. The source electrode 123 and the drain electrode 124 may be configured by copper (Cu), aluminum (Al), molybdenum (Mo), nickel (Ni), titanium (Ti), chrome (Cr), or an alloy thereof, but are not limited thereto. The source electrode 123 and the drain electrode 124 may be formed with the same material in the same process as the gate electrode 122, but are not limited thereto.

Each of the source electrode 123 and the drain electrode 124 may be disposed to be electrically connected to the active layer 121. The source electrode 123 and the drain electrode 124 may be disposed to be in contact with both ends of the active layer 121, respectively which is exposed without being covered by the insulating film ILD. That is, the source electrode 123 may be disposed to be in contact with one end of the active layer 121 and the drain electrode 124 may be disposed to be in contact with the other end of the active layer 121.

The source electrode 123 or the drain electrode 124 may be disposed to be in contact with the light shielding layer LS through a contact hole formed in the second buffer layer 112. When the light shielding layer LS is formed as an island shape so as to overlap the active layer 121, a parasitic capacitance may affect the performance of the thin film transistor 120. Accordingly, the light shielding layer LS is connected to the source electrode 123 or the drain electrode 124 to apply a voltage to minimize the influence of the parasitic capacitance. However, the structure of the present disclosure is not limited thereto, but may vary according to a structure and a design of the thin film transistor 120. As another example, the thin film transistor 120 may be formed as a bottom gate type thin film transistor in which the gate electrode 122 is disposed below the active layer 121. In this case, the gate electrode 122 disposed below the active layer 121 may serve as a light shielding layer.

The passivation layer 131 is disposed on the thin film transistor 120. The passivation layer 131 may suppress the degradation of the thin film transistor 120 due to external moisture or oxygen. For example, the passivation layer 131 may be formed of an inorganic insulating material, such as a silicon oxide film or a silicon nitride film, but is not limited thereto. If necessary, the passivation layer 131 may be optionally formed as a single layer or multiple layers.

The display device 100 according to the example embodiment of the present disclosure is driven in a bottom emission type in which light emitted from the light emitting diode 160 is emitted to the bottom of the display device 100. Therefore, the color filter 140 may be disposed on the passivation layer 131. The color filter 140 converts white light emitted from the light emitting diode 160 into red, green, and blue light. Therefore, the color filter 140 is disposed so as to correspond to the emission area of the light emitting diode 160. The color filter 140 converts white light emitted from the light emitting diode 160 into light with a color corresponding to each of the plurality of sub pixels to implement full color and improve color reproducibility. When the light emitting diodes 160 formed in the plurality of sub pixels emit red light, green light, and blue light, respectively, the color filter 140 may be omitted.

Planarization layers 151 and 152 are disposed on the thin film transistor 120 and the color filter 140. The planarization layers 151 and 152 are disposed on the thin film transistor 120 and the color filter 140 to provide flat surfaces. Therefore, optical distortion, such as a rainbow mura, may be suppressed.

The planarization layers 151 and 152 may include a first planarization layer 151 and a second planarization layer 152. The first planarization layer 151 is disposed so as to cover the thin film transistor 120 and the color filter 140. The second planarization layer 152 is disposed so as to cover at least a part of the first planarization layer 151. For example, the second planarization layer 152 may be disposed on the first planarization layer 151 so as to correspond to the emission area of the light emitting diode 160. However, it is not limited thereto and if necessary, the second planarization layer 152 may be optionally disposed on the entire surface of the first planarization layer 151.

The first planarization layer 151 and the second planarization layer 152 will be described below.

The light emitting diode 160 is disposed on the planarization layers 151 and 152. The light emitting diode 160 includes an anode 161, an organic emission layer 162, and a cathode 163. The anode 161 of the light emitting diode 160 is electrically connected to the source electrode 123 or the drain electrode 124 of the thin film transistor through contact holes formed in the planarization layers 151 and 152. Even though in the drawing, it is illustrated that the anode 161 is electrically connected to the source electrode 123, the present disclosure is not limited thereto. The anode 161 may also be electrically connected to the drain electrode 124.

The anode 161 is disposed on the planarization layers 151 and 152. The anode 161 may be formed of a conductive material having a high work function to supply holes to the organic emission layer 162. For example, the anode 161 may include a transparent conductive material, such as indium tin oxide (ITO) and indium zinc oxide (IZO), but is not limited thereto.

A bank BNK is disposed on the planarization layers 151 and 152 and the anode 161. The bank BNK is disposed on the planarization layers 151 and 152 so as to expose at least a part of the anode 161. That is, the bank BNK may be disposed on the planarization layers 151 and 152 so as to cover an edge of the anode 161. The bank BNK is an insulating layer disposed between the plurality of sub pixels to divide the plurality of sub pixels. At this time, an area which is exposed without being covered by the bank BNK may be defined as an emission area in which light is emitted. The bank BNK may be formed of an organic insulating material. For example, the bank BNK may be formed of polyimide, acryl, or benzocyclobutene (BCB) resin, but it is not limited thereto.

The organic emission layer 162 is disposed on the anode 161. The organic emission layer 162 may be an organic layer which emits light having a specific color. The organic emission layer 162 may be formed as one layer which is continuous over the entire active area. For example, the organic emission layer 162 may be configured to emit white light, but is not limited thereto. As another example, the organic emission layer 162 may be patterned so as to correspond to each of the plurality of sub pixels. In this case, the organic emission layer 162 may be configured to emit light having a color corresponding to each of the plurality of sub pixels. Further, in this case, the color filter 140 may be omitted.

The organic emission layer 162 may further optionally include various layers, such as a hole transport layer, a hole injection layer, a hole blocking layer, an electron injection layer, an electron blocking layer, or an electron transport layer, if necessary.

The cathode 163 is disposed on the organic emission layer 162. The cathode 163 may be formed as one layer which is continuous over the entire active area. That is, the cathode 163 may be a common layer which is commonly formed in the plurality of sub pixels. The cathode 163 supplies electrons to the organic emission layer 162 so that the cathode may be formed of a conductive material having a low work function. For example, the cathode 163 may be formed of a transparent conductive material such as indium tin oxide (ITO) or indium zinc oxide (IZO), or a metal such as magnesium (Mg) or silver (Ag), or an alloy including the metal, and may further include a metal doping layer, but is not limited thereto.

The display device 100 according to the example embodiment of the present disclosure may be driven in a bottom emission type in which light emitted from the organic emission layer 162 is emitted toward the bottom of the display device 100.

As described above, in the display device 100 which is driven in the bottom emission type, light emitted from the light emitting diode 160 is emitted to the bottom surface of the display device 100. In order to increase the light extraction efficiency by minimizing the loss of light emitted from the light emitting diode 160, the first planarization layer 151 and the second planarization layer 152 may be formed to have different refractive indices.

A refractive index of the anode 161 of the light emitting diode 160 is higher than a refractive index of the outside of the substrate 110 and the display device 100, that is, the air. Therefore, in order to minimize the loss of light emitted from the light emitting diode 160 to the bottom of the display device 100, the refractive index of the first planarization layer 151 adjacent to the substrate 110 is formed to be lower than the refractive index of the second planarization layer 152 adjacent to the anode 161. That is, the refractive index of the first planarization layer 151 is lower than the refractive index of the second planarization layer 152. In this case, when light emitted from the light emitting diode 160 is emitted to the bottom of the display device 100, the light loss generated in the display device 100 is minimized to improve the light extraction efficiency. p For example, the refractive index of the first planarization layer 151 is 1.45 to 1.50 and the refractive index of the second planarization layer 152 is 1.6 to 2.0. Further, the difference between the refractive index of the first planarization layer 151 and the refractive index of the second planarization layer 152 may be desirably 0.2 or larger. When the refractive indices of the first planarization layer 151 and the second planarization layer 152 and the refractive index difference are within the above-mentioned range, the light extraction efficiency of the display device 100 is improved to have an excellent display quality.

A micro lens array structure may be formed on the interface on which the first planarization layer 151 and the second planarization layer 152 are in contact. For example, the first planarizing layer 151 may have a plurality of convex portions and a plurality of concave portions. The convex portions of the first planarization layer 151 are disposed in the vicinity of the concave portions. That is, the concave portions and the convex portions of the first planarization layer 151 are alternately disposed. The second planarization layer 152 may be formed along a surface shape of the first planarization layer 151. Therefore, convex portions and concave portions may be formed on the bottom surface of the second planarization layer 152. Even though in the drawing, it is illustrated that cross-sections of the concave portion of the first planarization layer 151 and the convex portion of the second planarization layer 152 are semi-circular shapes, the present disclosure is not limited thereto.

The convex portions of the second planarization layer 152 and the concave portions of the first planarization layer 151 are engaged with each other to be in contact with each other. That is, the convex portion of the second planarization layer 152 is disposed to overlap the concave portion of the first planarization layer 151 and the concave portion of the second planarization layer 152 is disposed to overlap the convex portion of the first planarization layer 151. Therefore, a micro lens array structure may be formed on the interface on which the first planarization layer 151 and the second planarization layer 152 are in contact with each other. Accordingly, an incident angle of light emitted from the light emitting diode 160 is smaller than a total reflection critical angle when light is incident onto the interface of the first planarization layer 151 and the second planarization layer 152. Therefore, light emitted from the light emitting diode 160 is not lost due to the total reflection on the first planarization layer 151 and the second planarization layer 152, but travels at an angle which is close to a right angle toward the bottom surface of the display device 100, that is, the color filter 140. Therefore, the light extraction efficiency which is emitted to the outside of the display device 100 is improved to improve the luminance of the display device 100 and improve the display quality.

As described above, the planarization layers 151 and 152 provide flat surfaces. That is, the micro lens array shape is formed only on the interface in which the first planarization layer 151 and the second planarization layer 152 are in contact. Further, the top surface of the second planarization layer 152 which is disposed so as to correspond to the emission area of the light emitting diode 160 and the top surface of the first planarization layer 151 on which the second planarization layer 152 is not disposed may be flat. Therefore, the light extraction efficiency is improved without an optical distortion such as rainbow mura to significantly improve the display quality.

Hereinafter, a material which configures the first planarization layer 151 and the second planarization layer 152 will be described in detail.

First, the second planarization layer 152 is formed with a material having a refractive index higher than that of the first planarization layer 151. For example, the second planarization layer 152 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

As described above, in order to further improve the light extraction efficiency, the refractive index difference of the first planarization layer 151 and the second planarization layer 152 is desirably 0.2 or larger. Therefore, the first planarization layer 151 is formed to have a low refractive index which is 1.50 or lower.

For example, the first planarization layer 151 may be formed by curing a composition including an acrylic binder, (meth)acrylic acid-benzyl (meth)acrylic acid copolymer, and an initiator. The first planarization layer 151 formed as described above does not include low refractive particles or fluorine material, but has a low refractive index which is 1.50 or lower and has excellent adhesiveness with the upper and lower layers so that the excellent reliability is provided while improving the light extraction efficiency of the display device 100. In the related art, as the exposure, development, and baking processes proceed, a surface roughness of the low refractive planarization layer formed of siloxane-acrylic fluorine resin is increased (approximately 5 nm level) so that there is a problem of degradation of the luminous efficiency. According to the present disclosure, the first planarization layer 151 is formed to include acrylic binder and (meth)acrylic acid-benzyl (meth)acrylic acid copolymer and the roughness thereof is 2 nm or lower after the exposure, development, and baking processes. Therefore, when the first planarization layer 151 according to the present disclosure is provided, there is an advantage of excellent light extraction efficiency.

For example, the first planarization layer 151 may be formed by curing a composition including 65 to 75% by weight of solvent, 10 to 20% by weight of acrylic binder, 10 to 20% by weight of (meth)acrylic acid-benzyl (meth)acrylic acid copolymer, and 0.2 to 10% by weight of an initiator based on 100% by weight of the composition. In this case, the light extraction efficiency is excellent with the low refractive characteristic and the adhesiveness with the upper and lower layers is improved to ensure the excellent reliability of the display device 100.

(Meth)acrylic acid-benzyl (meth)acrylic acid copolymer improves developability in the post-exposure development step when the first planarization layer 151 is formed by a photolithography process, and acts as a crosslinking agent for an acrylic binder to improve the density of the first planarization layer 151. Therefore, the display device 100 with an excellent reliability may be provided by improving adhesiveness with layers above and below the first planarization layer 151. Further, the thermal stability of the first planarization layer 151 is improved to enable a high temperature process.

Further, when a content of the initiator in the composition is high, the yellowing degree of the first planarization layer 151 may increase in a high temperature process, thereby reducing the transmittance. The first planarization layer 151 of the present disclosure is produced with a composition having a low initiator content of 0.2 to 10% by weight and has a high thermal stability of the composition to improve the yellowing degree so that the problem of the related art in that the transmission is degraded in a short wavelength band may be solved. Further, there is a tendency that the higher the initiator content, the higher the refractive index of the first planarization layer 151 so that in order to ensure the low refractive characteristic, it is desirable to control the initiator content within the above-described range.

Further, when a predetermined level or more of metal catalyst remains in the composition remains, the yellowing degree may be increased after the high temperature process. Therefore, a residual amount of the metal catalyst in the composition is desirably maintained to be low at a level of 0.02 to 0.05 ppm. Within this range, the first planarization layer 151 has a high transmittance of 99% or higher within a broad wavelength band of 380 nm to 780 nm and has an excellent optical characteristic with a low yellowing degree and a haze so that the display quality of the display device 100 may be significantly improved. When a residual amount of the metal catalyst exceeds 0.05 ppm, the yellowing degree and the haze value are high and the transmittance is degraded in the short wavelength band of 380 nm, which may degrade the display quality. Further, when the residual amount of the metal catalyst is 0.02 ppm or lower, there is a problem in that a residual film remains after the photolithography process.

For example, the acrylic binder may be one or more selected from the group consisting of methyl methacrylate, ethyl methacrylate, n-butyl methacrylate, sec-butyl methacrylate, tert-butyl methacrylate, methyl acrylate, isopropyl acrylate, cyclohexyl methacrylate, 2-methylcyclohexyl methacrylate, dicyclopentenyl acrylate, dicyclopentanyl acrylate, dicyclopentenyl methacrylate, dicyclopentanyl methacrylate, 1-adamantyl acrylate, 1-adamantyl methacrylate, dicyclopentanyloxyethyl methacrylate, isoboronyl methacrylate, cyclohexylacrylate, 2-methylcyclohexylacrylate, dicyclopentanyloxyethyl acrylate, isoboronyl acrylate, phenyl methacrylate, phenyl acrylate, and benzyl acrylate, but is not limited thereto.

If necessary, the acrylic binder may optionally further include acrylic multifunctional monomer. In this case, the developability may be improved and the residual film may be minimized during the photolithography process. For example, the acrylic multifunctional monomer may be one or more selected from the group consisting of 1,4-butanediol diacrylate, 1,3-butylene glycol diacrylate, ethylene glycol diacrylate, trimethylolpropane diacrylate, trimethylolpropane triacrylate, pentaerythritol triacrylate, pentaerythritol tetraacrylate, triethylene glycol diacrylate, polyethylene glycol diacrylate, dipentaerythritol hexaacrylate, dipentaerythritol tridiacrylate, dipentaerythritol diacrylate, sorbitol triacrylate, bisphenol A diacrylate derivatives, dipentaerythritol polyacrylate, and methacrylates, fluorinated acrylates, and fluorinated methacrylates, but is not limited thereto.

The solvent may facilitate the photolithography process by controlling the spreadability of the composition. For example, the solvent may be one or more selected from a group consisting of ethylene glycol monoalkyl ethers, propylene glycol monoalkyl ethers, dipropylene glycol alkyl ethers, butylene glycol monomethyl ethers, dibutylene glycol alkyl ethers, diethylene glycol dimethyl ether, diethylene glycol methyl ethyl ether, propylene glycol methyl ether acetate, propylene glycol ethyl ether acetate, propylene glycol propyl ether acetate, propylene glycol methyl ether propionate, propylene glycol ethyl ether propionate, propylene glycol propyl ether propionate, propylene glycol methyl ether, propylene glycol ethyl ether, propylene glycol propyl ether, propylene glycol butyl ether, dipropylene glycol dimethyl ether, dipropylene glycol diethyl ether, butylene glycol monomethyl ether, butylene glycol monoethyl ether, dibutylene glycol dimethyl ether, dibutylene glycol diethyl ether, diethylene glycol butyl methyl ether, diethylene glycol butyl ethyl ether, triethylene glycol dimethyl ether, triethylene glycol butyl methyl ether, diethylene glycol tertiary butyl ether, tetraethylene glycol dimethyl ether, diethylene glycol ethylhexyl ether, diethylene glycol methylhexyl ether, dipropylene glycol butyl methyl ether, dipropylene glycol ethylhexyl ether, and propylene glycol methylhexyl ether, but is not limited thereto.

For example, the initiator may be one or more selected from the group consisting of 1-[4-(phenylthio)phenyl]-1,2-octanedione 2-(O-benzoyloxime), 1-{6-[4-(2,2-dimethyl-[1,3]dioxalan-4-ylmethyl)-benzoyl]- 9-ethyl-9H-carbazol-3-yl}-ethanoneoxime-O-acetate, 1-[9-ethyl-6-(4-diethylamino-4-benzoyl)-9H-carbazol-3-yl]-ethanoneoxime-O-acetate, 1-[9-ethyl-6-(4-phenylsulfanyl-4-benzoyl)-9H-carbazol-3-yl]-ethanoneoxime-O-acetate, 1-[9-ethyl-6-(4-(2,6-dimethyl- morpholine)-4-benzoyl)-9H-carbazol-3-yl]-ethanoneoxime-O-acetate, 1-[9-ethyl-6-(2-methyl-benzoyl)-9H-carbazol-3-yl]-ethanoneoxime-O-acetate, 1-{6-[4-(2,2-dimethyl-[1,3]dioxalan-4-ylmethyl)-2-methyl-benzoyl]-9-ethyl-9H-carbazol-3-yl}-ethanoneoxime-O-acetate, and 1-[9-ethyl-6-(2-methyl-4-morpholin-4-yl-benzoyl)-9H-carbazol-3-yl]-ethanoneoxime-O-acetate, but is not limited thereto.

A composition for forming the first planarization layer 151 may further include a low-refractive compound that has a bulky function group to lower the refractive index, thereby making the first planarization layer 151 with a porous structure. For example, the low refractive compound may be at least one of a polystyrene block copolymer, dodecyl (meth)acrylate, and acrylic acid containing a cyclic olefin group.

For example, the polystyrene block copolymer may include one or more selected from compounds represented by the following Formulae 1 and 2.

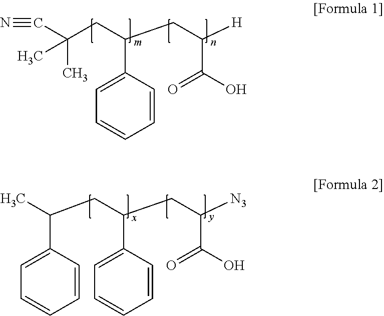

For example, m and n in Formula 1 and x and y in Formula 2 may be independently integers of 1 to 100.

For example, the acrylic acid containing a cyclic olefin group may be 5-norbornene-2-acrylic acid, but is not limited thereto.

Such compounds may have a relatively large functional group within the molecule to form a porous structure within the first planarization layer 151. Therefore, the refractive index of the first planarization layer 151 may be formed to be low.

For example, the low refractive compound may be included in an amount of 0.1 to 50 parts by weight based on 100 parts by weight of the acrylic binder and within this range, the refractive index of the first planarization layer 151 is lowered to further improve the light extraction efficiency.

A composition for forming the first planarization layer 151 may further include a thermosetting monomer including at least one or more of epoxy group and hydroxyl group. This improves the thermal stability to facilitate the high temperature process and suppress the increase of the yellowing degree to maintain the light transmittance to be high.

For example, the thermosetting monomer may be a monomer including a functional group such as oxetane or tetrahydrofuran. For example, the thermosetting monomer may be included in an amount of 1 to 40 parts by weight based on 100 parts by weight of the acrylic binder and within this range, the heat resistance of the first planarization layer 151 is excellent.

The composition for forming the first planarization layer 151 may further include one or more unsaturated carboxylic acids selected from acrylic acid, methacrylic acid, maleic acid, fumaric acid, citraconic acid, metaconic acid, and itaconic acid. This improves the solubility of the acrylic binder to provide the first planarization layer 151 with a uniform physical property. For example, the unsaturated carboxylic acid may be included in an amount of 1 to 30 parts by weight based on 100 parts by weight of the acrylic binder and within this range, the solubility of the acrylic binder may be improved without degrading the physical property of the first planarization layer 151.

If necessary, the composition for forming the first planarization layer 151 may further include additives, such as a coupling agent or a UV absorbent. The additive may be included in the amount of 0.1 to 30 parts by weight based on 100 parts by weight of acrylic binder, but is not limited thereto.

The coupling agent improves the adhesiveness with upper and lower layers. For example, the coupling agent may be one or more selected from the silane coupling agents, such as (3-glycideoxypropyl)trimethoxysilane, (3-glycideoxypropyl)triethoxysilane, (3-glycideoxypropyl)methyldimethoxysilane, (3-glycideoxypropyl)methyldiethoxysilane, (3-glycideoxypropyl)dimethylethoxysilane, 3,4-epoxybutyltrimethoxysilane, 3,4-epoxybutyltriethoxysilane, 2-(3,4-epoxycyclohexyl)ethyltrimethoxysilane, 2-(3,4-epoxycyclohexyl)ethyltriethoxysilane, aminopropyltrimethoxysilane, aminopropyltriethoxysilane, 3-triethoxysili-N-(1,3 dimethyl-butylidene)propylamine, N-(2-aminoethyl)-3-aminopropyltrimethoxysilane, N-(2-aminoethyl)-3-aminopropyltriethoxysilane, N-(2-aminoethyl) 3-aminopropylmethyldimethoxysilane, N-phenyl-3-aminopropyltrimethoxysilane, and (3-isocyanatepropyl)triethoxysilane, but is not limited thereto.

For example, the coupling agent may be included in an amount of 0.1 to 10 parts by weight based on the 100 parts by weight of acrylic binder and the adhesiveness is excellent within this range.

The UV absorbent absorbs unnecessary UV to suppress degradation due to the light and improve the optical characteristic. For example, the UV absorbent may include benzophenones, triazines, benzotriazoles, oxanilides, etc. but is not limited thereto. For example, the UV absorbent may be included in an amount of 0.1 to 10 parts by weight based on 100 parts by weight of acrylic binder.

The first planarization layer 151 formed as described above does not include a fluorine compound having hydrophobicity and low refractive particles, such as porous silica, but has a low refractive characteristic. Therefore, there is an advantage of excellent adhesiveness with upper and lower layers of the first planarization layer 151. Therefore, a display device 100 with excellent processability and reliability is provided.

According to the example embodiment of the present disclosure, a surface of the first planarization layer 151 and a surface of the second planarization layer 152 may be independently plasma-processed with gas selected from oxygen, nitrogen, hydrogen, and helium. In this case, a surface energy of the first planarization layer 151 and the second planarization layer 152 is increased and a contact angle is decreased to provide the hydrophilicity. Therefore, the adhesiveness between the first planarization layer 151 and the second planarization layer 152 and the adhesiveness between the first planarization layer 151 and the second planarization layer 152, and the anode 161 may be further increased. Specifically, the adhesiveness may be further improved by the plasma treatment with nitrogen, hydrogen, or helium gas and the defect such as crack and/or loss of the anode 161 may be suppressed.

The display device 100 according to the example embodiment of the present disclosure includes the first planarization layer 151 including an acrylic binder and (meth)acrylic acid-benzyl (meth)acrylic acid copolymer. Even though the first planarization layer 151 of the present disclosure does not include low refractive particles or fluorine-based material, the first planarization layer has a low refractive characteristic and excellent adhesiveness with upper and lower layers, and facilitates formation of the lens shape through the photolithography process. Accordingly, the display device 100 including the first planarization layer 151 according to the present disclosure has an advantage on the process and improves the light extraction efficiency to provide excellent display quality. Further, the adhesiveness of the first planarization layer 151 is improved so that there is no change of the optical characteristic after high temperature/high humidity reliability evaluation and defects such as loss or crack of the anode 161 are improved.

Hereinafter, the effects of the present disclosure which have been described above will be described with reference to Examples. However, the following Examples are set forth to illustrate the present disclosure, but the scope of the present disclosure is not limited thereto.

### EXAMPLE 1

A mixture was prepared by mixing 10 to 20 parts by weight of an acrylic binder, 20 parts by weight of a methacrylic acid-benzyl methacrylic acid copolymer, 72 parts by weight of propylene glycol monomethyl ether acetate as a solvent, 5 parts by weight of 2-(O-benzoyloxime)-1-[4-(phenylthio)phenyl]-1,2-octanedione as an initiator, 1 part by weight of 2,4-bis(2-hydroxy-4-butoxyphenyl)-6-(2,4-dibuoxyphenyl)-1,3,5-triazine as a UV absorbent, 1 part by weight of (3-isocyanatepropyl)triethoxysilane as a silane coupling agent, and 1 part by weight of a silicone surfactant. Propylene glycol monoethyl acetate was added so that the solid content of the mixture was 20 to 30 parts by weight, and the mixture was dissolved to prepare a photosensitive resin composition for the first planarization layer. A low refractive planarization layer was formed on the base material using this.

### Comparative Example 1

A low refractive planarization layer was formed on the base material with a photosensitive resin composition for the first planarization layer which included the acrylic binder, excluding the methacrylic acid-benzyl methacrylic acid copolymer from Example 1.

### Comparative Examples 2 to 6

A low refractive planarization layer was formed on the base material with a photosensitive resin composition for the first planarization layer including the siloxane binder and the acrylic binder at a ratio described in the following Table 1.

### Experimental Example 1

A refractive index and a surface roughness of a specimen of each of Example 1 and Comparative Example 1 were measured and the result thereof was represented in the following Table 1.

TABLE 1

| | | | Ex. | Comp. Ex. |
|---|---|---|---|---|
| | | | 1 | 1 |
| Weight ratio of siloxane to acryl | | | 0:100 | 0:100 |
| Refractive index | | | 1.508 | 1.56 |
| | Roughness | Ra (nm) | 1.05 | 1.76 |
| | | Rq (nm) | 2.00 | 2.07 |

With reference to Table 1, it is confirmed that the low refractive layer formed by a composition for forming a first planarization layer according to Example 1 has a low refractive index and a low surface roughness. Therefore, it is understood that when the low refractive planarization layer according to the present disclosure is included, the light extraction efficiency may be improved.

Unlike Example 1, it is confirmed that the low refractive planarization layer of Comparative Example 1 which does not include methacrylic acid-benzyl methacrylic acid copolymer has a higher refractive index and a higher surface roughness than those of Example 1.

### Experimental Example 2

A refractive index and a surface roughness of a specimen of each of Example 1 and Comparative Examples 2 to 6 were measured and the result thereof was represented in the following Table 2.

TABLE 2

| | | | Comp. | Comp. | Comp. | Comp. | Comp. |
|---|---|---|---|---|---|---|---|
| | | EX. 1 | Ex. 2 | Ex. 3 | Ex. 4 | Ex. 5 | Ex. 6 |
| Weight ratio of | | 0:100 | 25:75 | 35:65 | 45:55 | 55:45 | 65:35 |
| siloxane to acryl | | | | | | | |
| Refractive index | | 1.508 | 1.502 | 1.501 | 1.499 | 1.493 | 1.476 |
| Rough- | Ra(nm) | 1.05 | 3.07 | 4.04 | 4.14 | 4.34 | 7.38 |
| ness | Rq(nm) | 2.00 | 3.90 | 5.11 | 5.19 | 5.46 | 9.31 |

With reference to Table 2, it is confirmed that the low refractive layer formed by a composition for forming a first planarization layer according to Example 1 has a low refractive index and a low surface roughness. Therefore, it is understood that when the low refractive planarization layer according to the present disclosure is included, the light extraction efficiency may be improved.

With reference to Comparative Examples 2 to 6 together, it is confirmed that when the acrylic binder and the siloxane binder are mixed, the higher the content of the siloxane binder, the lower the refractive index, but the surface roughness is significantly increased.

As can be seen from Comparative Examples 2 to 6 above, the refractive index and roughness have a complementary relationship. Therefore, it is understood that the low refractive planarization layer of Example 1 formed with a composition including a methacrylic acid-benzyl methacrylic acid copolymer and not including a siloxane-based binder has the lowest surface roughness and a low refractive index, making it effective in reducing reflectance.

### Experimental Example 3

Experimental Example 3 is carried out to find out an electro-optical characteristic of a unit cell including a low refractive planarization film of each of Example 1 and Comparative Examples 1 and 7. Comparative Example 7 was prepared with a low refractive planarization layer including a fluorine containing acrylic resin. The result was represented in the following Table 3.

TABLE 3

| | | Ex. | Comp. Ex. | Comp. Ex. |
|---|---|---|---|---|
| | | 1 | 1 | 7 |
| Refractive index | | 1.50 | 1.56 | 1.46 |
| Electro-optical | Luminous efficiency | 92.9 | 88.4 | 90.7 |
| characteristic | CIE_X | 0.284 | 0.290 | 0.288 |
| | CIE_Y | 0.286 | 0.294 | 0.289 |

With reference to Table 3, it is confirmed that the unit cell equipped with the low refractive planarization layer according to Example 1 has excellent color reproducibility and the highest luminous efficiency.

As described above, the low refractive planarization layer of Example 1 according to the present disclosure has advantages of a refractive index lower than that of Comparative Example 1 and a low surface roughness. Therefore, according to Example 1, it is confirmed that the adhesiveness between the low refractive planarization layer and an upper layer thereof is improved to have a superior luminous efficiency to Comparative Example 1. When the fluorine containing acrylic resin which is used for a material of the low refractive planarization layer in the related art is included, the refractive index is low due to the fluorine component, but it has a hydrophobicity so that a poor adhesiveness with the upper layer is provided. Therefore, it is confirmed that in Comparative Example 7, the refractive index of the low refractive planarization layer is lower than that of Example 1, but the efficiency is lower than that of Example 1.

### Experimental Example 4

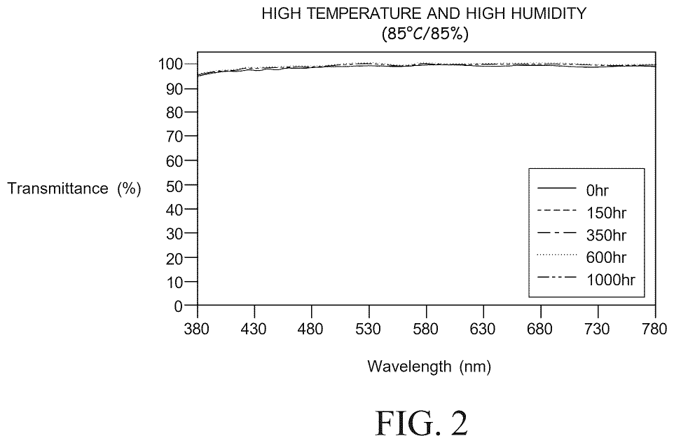

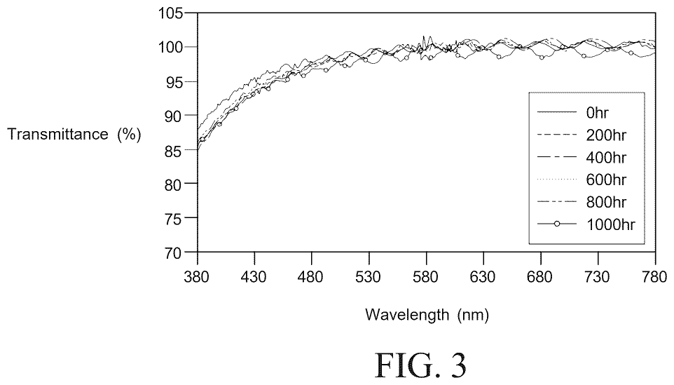

A high temperature and high humidity reliability of the low refractive planarization layer according to Example 1 was evaluated. The high temperature and high humidity reliability were evaluated by measuring a transmittance after storing a specimen of Example 1 under a condition of a temperature of 85 degrees and a relative humidity of 85% for 0 to 1000 hours. The result was represented in FIG. 2. For the comparison, an evaluation result of the high temperature reliability of a low refractive planarization layer according to Comparative Example 1 was represented in FIG. 3.

FIG. 2 is a graph illustrating a result of evaluating high temperature (85° C.) and high humidity (85%) reliability of Example 1. FIG. 3 is a graph illustrating a result of evaluating high temperature (60° C.) reliability of Comparative Example 1.

With reference to FIG. 2, it is confirmed that even though the low refractive planarization layer according to Example 1 was stored for up to 1000 hours under the high temperature and high humidity condition, there was no change in the light transmittance.

In contrast, with reference to FIG. 3, even though the low refractive planarization layer according to Comparative Example 1 was not stored under the high temperature condition (0 hour), the transmittance was lowered in a short wavelength band of 380 nm to 430 nm. Further, even though the experiment was conducted on the low refractive planarization layer according to Comparative Example 1 under a temperature condition of 60 degrees which is lower than Example 1, the transmittance was significantly lowered in the short wavelength band.

Accordingly, it is understood that the low refractive planarization layer formed according to the present disclosure has an excellent reliability for the high temperature and high humidity environment.

The example embodiments of the present disclosure can also be described as follows:

According to an aspect of the present disclosure, there is provided a display device. The display device comprises a substrate; a thin film transistor disposed on the substrate; a planarization layer disposed on the thin film transistor; and a light emitting diode disposed on the planarization layer, wherein the planarization layer includes a first planarization layer which is disposed so as to cover the thin film transistor and a second planarization layer which is disposed so as to cover at least a part of the first planarization layer and a refractive index of the first planarization layer is lower than that of the second planarization layer, and the first planarization layer includes (meth)acryl acid-benzyl (meth)acryl acid copolymer.

The display device may further comprises a passivation layer which is disposed so as to cover the thin film transistor; and a color filter disposed on the passivation layer so as to correspond to an emission area of the light emitting diode, wherein the planarization layer may be disposed so as to cover the color filter.

A refractive index of the first planarization layer may be 1.45 to 1.50 and a refractive index of the second planarization layer is 1.6 to 2.0.

The second planarization layer may be disposed on the first planarization layer so as to correspond to an emission area of the light emitting diode.

At least a part of a surface of the second planarization layer which is in contact with the first planarization layer may include a convex portion and at least a part of a surface of the first planarization layer which is in contact with the second planarization layer may include a concave portion corresponding to the convex portion and the convex portion and the concave portion may be engaged with each other to be in contact with each other.

The first planarization layer may be a cured material of a composition including the acrylic binder, the (meth)acrylic acid-benzyl (meth)acrylic acid copolymer, and an initiator.

The composition may further include at least one low refractive compound of a polystyrene block copolymer, dodecyl (meth)acrylate, and acrylic acid containing a cyclic olefin group.

The polystyrene block copolymer may include one or more selected from compounds represented by the following Formulae 1 and 2:

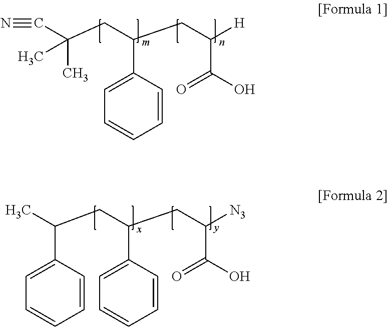

(in which m and n in Formula 1 and x and y in Formula 2 are independently integers of 1 to 100).

The composition may further include a thermosetting monomer including at least one or more of epoxy group and hydroxyl group.

The composition may further include one or more unsaturated carboxylic acids selected from the group consisting of acrylic acid, methacrylic acid, maleic acid, fumaric acid, citraconic acid, metaconic acid, and itaconic acid.

The composition may include 65 to 75% by weight of solvent, 10 to 20% by weight of the acrylic binder, 10 to 20% by weight of the (meth)acrylic acid-benzyl (meth)acrylic acid copolymer, and 0.2 to 10% by weight of the initiator based on 100% by weight of the composition.

The low refractive compound may be included in an amount of 0.1 to 50 parts by weight based on 100 parts by weight of the acrylic binder.

The thermosetting monomer may be included in an amount of 1 to 40 parts by weight based on 100 parts by weight of the acrylic binder.

The unsaturated carboxylic acid may be included in an amount of 1 to 30 parts by weight based on 100 parts by weight of the acrylic binder.

A surface of the first planarization layer and a surface of the second planarization layer may be plasma-treated with gas selected from oxygen, nitrogen, hydrogen, and helium.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a thin film transistor disposed on the substrate;
a planarization layer disposed on the thin film transistor; and
a light emitting diode disposed on the planarization layer,
wherein the planarization layer includes a first planarization layer which is disposed so as to cover the thin film transistor and a second planarization layer which is disposed so as to cover at least a part of the first planarization layer, and
a refractive index of the first planarization layer is lower than that of the second planarization layer, and the first planarization layer includes (meth)acryl acid-benzyl (meth)acryl acid copolymer.

2. The display device according to claim 1, further comprising:
a passivation layer which is disposed so as to cover the thin film transistor; and
a color filter disposed on the passivation layer so as to correspond to an emission area of the light emitting diode,
wherein the planarization layer is disposed so as to cover the color filter.

3. The display device according to claim 1, wherein a refractive index of the first planarization layer is 1.45 to 1.50 and a refractive index of the second planarization layer is 1.6 to 2.0.

4. The display device according to claim 1, wherein the second planarization layer is disposed on the first planarization layer so as to correspond to an emission area of the light emitting diode.

5. The display device according to claim 1, wherein at least a part of a surface of the second planarization layer which is in contact with the first planarization layer includes a convex portion, and
at least a part of a surface of the first planarization layer which is in contact with the second planarization layer includes a concave portion corresponding to the convex portion, and
the convex portion and the concave portion are engaged with each other to be in contact with each other.

6. The display device according to claim 1, wherein the first planarization layer is a cured material of a composition including the acrylic binder, the (meth)acrylic acid-benzyl (meth)acrylic acid copolymer, and an initiator.

7. The display device according to claim 6, wherein the composition further includes at least one low refractive compound of a polystyrene block copolymer, dodecyl (meth)acrylate, and acrylic acid containing a cyclic olefin group.

8. The display device according to claim 7, wherein the polystyrene block copolymer includes one or more selected from compounds represented by the following Formulae 1 and 2: 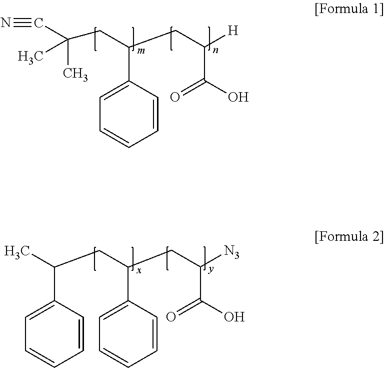
where m and n in Formula 1 and x and y in Formula 2 are independently integers of 1 to 100.

9. The display device according to claim 6, wherein the composition further includes a thermosetting monomer including at least one or more of epoxy group and hydroxyl group.

10. The display device according to claim 6, wherein the composition further includes one or more unsaturated carboxylic acids selected from the group consisting of acrylic acid, methacrylic acid, maleic acid, fumaric acid, citraconic acid, metaconic acid, and itaconic acid.

11. The display device according to claim 6, wherein the composition includes 65 to 75% by weight of solvent, 10 to 20% by weight of the acrylic binder, 10 to 20% by weight of the (meth)acrylic acid-benzyl (meth)acrylic acid copolymer, and 0.2 to 10% by weight of the initiator based on 100% by weight of the composition.

12. The display device according to claim 7, wherein the low refractive compound is included in an amount of 0.1 to 50 parts by weight based on 100 parts by weight of the acrylic binder.

13. The display device according to claim 9, wherein the thermosetting monomer is included in an amount of 1 to 40 parts by weight based on 100 parts by weight of the acrylic binder.

14. The display device according to claim 10, wherein the unsaturated carboxylic acid is included in an amount of 1 to 30 parts by weight based on 100 parts by weight of the acrylic binder.

15. The display device according to claim 1, wherein a surface of the first planarization layer and a surface of the second planarization layer are plasma-treated with gas selected from oxygen, nitrogen, hydrogen, and helium.
